(19) United States
(12) Patent Application Publication
(10) Pub. No.: US 2006/0220167 A1
(43) Pub. Date: Oct. 5, 2006

(54) IC package with prefabricated film capacitor

(75) Inventors: Yongki Min, Phoenix, AZ (US); Islam A. Salama, Chandler, AZ (US)

Correspondence Address: SCHWABE, WILLIAMSON & WYATT, PACWEST CENTER, SUITE 1900, 1211 S.W. FIFTH AVE., PORTLAND, OR, 97204, US

(73) Assignee: Intel Corporation

(21) Appl. No.: 11/095,690

(22) Filed: Mar. 31, 2005

(51) Int. Cl. B32B 37/00; H01L 21/00

(52) U.S. Cl. 257/499; 156/60; 438/381; 156/153; 156/272.8

(57) ABSTRACT

A method of fabricating an integrated circuit package, comprising prefabricating a film capacitor including forming a first conductive layer, depositing a dielectric layer on the first conductive layer, and depositing a second conductive layer on the dielectric layer; forming a substrate; and laminating the prefabricated film capacitor to the substrate.

### BACKGROUND

1. Technical Field

Embodiments of the present invention are related to the field of electronic devices, and in particular, to integrated circuit packages.

2. Description of Related Art

An integrated thin film capacitor (TFC) may be embedded in an integrated circuit (IC) package adjacent to a die. The TFC, which may be referred to a decoupling capacitor, stores charge to provide a stable power supply by decoupling the supply from high frequency noise, damping power overshoots when the die is powered up, and damping power droops when the die begins to use power. Inductance between the TFC and the die slows response time of the TFC to voltage changes. By embedding the TFC in close proximity to the die, this inductance may be reduced.

The TFC typically is a multilayer structure with at least one pair of conductive layers (electrodes) coupled between the supply voltage and ground and separated by a dielectric layer or film. Among various dielectric materials, hi-k ceramic materials show the highest dielectric constants (600-4000). However, hi-k ceramic thin films need high temperature processing (e.g., furnace annealing at 600-800 C.) to have these high dielectric constants. Thus, embedding a hi-k thin film into a substrate of an IC package with an organic material generally is considered difficult due to the low melting point of the organic material.

TFCs may be made by sputtering conductive materials; however, the resulting conductive layers may have smooth surfaces. A roughening process utilizing a wet etching process (e.g., CZ treatment) has been used to increase adhesion to an organic build-up material. However, since the electrode layers of a TFC are so thin, it is generally not practical to apply the CZ process to the TFC to improve adhesion. One approach to allow use of the CZ process would be to attempt to increase the electrode thickness of TFC and then use the CZ process for surface roughening. However, it is very often difficult to achieve a sputtered thick film due to the induced stress during the deposition.

### BRIEF DESCRIPTION OF THE DRAWINGS

FIG. 1 illustrates a cross-sectional view of an IC package in accordance with one embodiment of the present invention.

FIG. 2 is a process flow for fabrication of the IC package of FIG. 1, in accordance with one method of the present invention.

FIGS. 3A-3C illustrate cross-sectional views of the IC package of FIG. 1 as it is being fabricated according to the process flow of FIG. 2.

FIG. 4 is an enlarged view of a segment of the IC package of FIG. 1.

FIG. 5 is an enlarged view of a segment of an IC package in accordance with another embodiment of the present invention.

FIG. 6 is a process flow for fabrication of the IC package of FIG. 5, in accordance with another method of the present invention.

FIGS. 7A-7E illustrate cross-sectional views of the IC package of FIG. 5 as it is being fabricated according to the process flow of FIG. 6.

FIG. 8 illustrates a cross-sectional view of an IC package in accordance with another embodiment of the present invention.

FIG. 9 is a diagram of a sputtering apparatus which may be used for at least one stage of the process flow of FIG. 2.

FIG. 10 is a block diagram of a system incorporating the IC packages according to the various embodiments of the present invention.

### DETAILED DESCRIPTION OF ILLUSTRATIVE EMBODIMENTS

In the following description, for purposes of explanation, numerous details are set forth in order to provide a thorough understanding of the disclosed embodiments of the present invention. However, it will be apparent to one skilled in the art that these specific details are not required in order to practice the disclosed embodiments of the present invention.

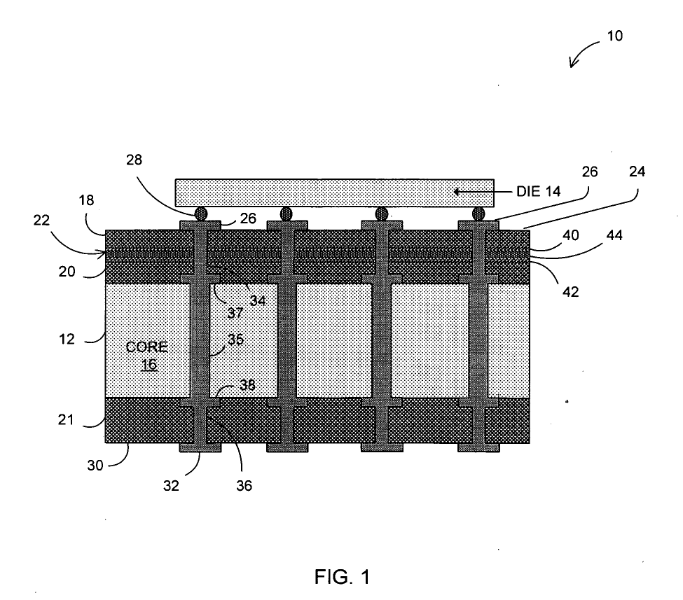

Referring to FIG. 1, an integrated circuit (IC) package 10 includes a substrate 12 and a die 14 carried by the substrate 12. In one embodiment, the substrate 12 may be a high density interconnect (HDI) substrate. In one embodiment, the substrate 12 may have a core 16, two build-up layers 18 and 20 on one side of the core 16, and a third build-up layer 21 on the other side of the core 16. An integrated thin film capacitor (TFC) 22 may be embedded in the substrate 12 by being sandwiched between the build-up layers 18 and 20 so as to be disposed adjacent to the die 14 to reduce inductance. The buildup layers 18, 20, 21 may be comprised of an organic material such as ajinimoto buildup film (ABF). In another embodiment, the build-up layers 18, 20, 21 may be comprised of other dielectric organic materials. In one embodiment, the core 16 may use FR4 (a flame retarding glass/epoxy material), FR5 or organic materials such as silica reinforced epoxy material. In another embodiment, the core 16 may be comprised of other dielectric materials.

In one embodiment, the substrate 12 may include a first surface 24 having an array of die pads 26 for electrically coupling the substrate 12 to the die 14 via solder bumps 28. The substrate 12 may have a second surface 30 with an array of land pads 32 for electrically coupling the substrate 12 to a printed circuit board (not shown) via solder balls (not shown). In one embodiment, the substrate 12 may further include a plurality of vias 34, plated-through-hole (PTH) vias 35, vias 36, metal via pads 37, and metal via pads 38, which combine to form the electrical paths for power and ground between the land pads 32 and die pads 26. The vias 34, 35, and 36 may form electrical conductive paths through insulating layers to connect conductive layers, pads or planes in two or more different layers. More specifically, each of the vias 34 may traverse the build-up layers 18 and 20 and the TFC 22 to electrically connect one of the die pads 26, one of the metal via pads 37, and one of the conductive layers of the TFC 22 (to be described hereinafter). Each of the PTH vias 35 may traverse the core 16 to electrically connect one of the metal via pads 37 to one of the metal via pads 38. Each of the vias 36 may traverse the build-up layer 21 to couple one of the metal via pads 38 to one of the land pads 32. The via pads 37 and 38 may be elongated (not shown) to allow the array of land pads 32 to be contained in a surface area larger than that of the die pads 26. Although FIG. 1 illustrates a land grid array (LGA) package, the IC package 10 may incorporate different forms of substrate-to-board interconnects, such as use of a pin or a ball array instead of a land pad array. Likewise, although the IC package 10 is illustrated in FIG. 1 with an array of die pads 26, the IC package 10 may incorporate different forms of die-to-substrate interconnects, such as wire bonding or tap automatic bonding (TAB).

The TFC 22 may be a multilayer structure with at least one pair of conductive layers 40 and 42 electrically coupled to a power supply (supply voltage Vcc) and a ground (ground voltage Vss). The conductive layers may be thin film electrode layers formed from, for example, copper (Cu) or nickel (Ni) foils. The conductive layers 40 and 42 are separated by a dielectric layer 44. The dielectric layer 44 may be a thin film formed of a hi-k ceramic material with a dielectric constant in a range of 600-4000. In one embodiment, the hi-k ceramic material may be BaSrTiO₃ (BST). The conductive layers 40 and 42 form parallel plates of a parallel-plate capacitor. The integrated TFC 22 may provide relatively low inductance and reduced number of vias 34, in addition to providing adequate capacitance for short durations.

As previously described in the Background, the hi-k ceramic dielectric layer 44 needs high temperature processing (e.g., furnace annealing at 600-800 C.) to achieve its high dielectric constant and such high temperature processing conflicts with the low melting point of substrate 12 having an organic material. To overcome this conflict, the TFC 22 is separately fabricated so that the high temperature processing does not affect the organic layers or portions of the substrate 12. Hence, the TFC 22 may be referred to as a “prefabricated” or “preformed” TFC 22.

As a result of the above-described prefabrication, in one embodiment, the prefabricated TFC may be laminated onto the build-up layer 20 of the substrate 12 so as to avoid the melting issue of the substrate 12. However, the lamination of the prefabricated TFC 22 to the substrate 12 may create two issues. A first issue involves bonding adhesion and de-lamination between the TFC 22 and the build-up layer 20 that may be encountered during the TFC integration into IC package 10. In selecting a reliable lamination method for bonding, it should be noted that the hi-k ceramic film 44 has a thickness of approximately 1 um; hence, it is fragile to most acids. Even weak acids may preferentially attack the grain boundary of hi-k films, and degrade their electrical performance. Additionally, the handling of a TFC of such thin dimensions may be difficult. As a second issue, a pre-patterned TFC may have difficulties with lamination alignment accuracy.

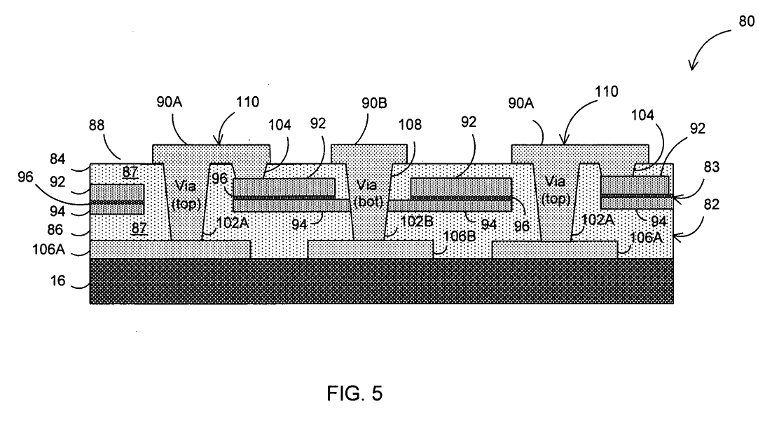

The IC package 10 of FIGS. 1-4, according to one embodiment of the present invention, is directed toward the above-described bonding issue. An IC package 80 of FIGS. 5-7, according to another embodiment of the present invention, is directed toward the above-described lamination alignment accuracy issue. The reference numbers shown in FIG. 1 will be used for both IC packages 10 and 80 to the extent that the components do not change between the two IC packages. In both embodiments, a thin film capacitor may be fabricated separately from the substrate due to the high temperature processing of the hi-k dielectric film in a furnace (600-800 C.). In these embodiments, the prefabricated TFC may be laminated to the build-up layer of the substrate. In other embodiments to be described hereinafter, the prefabricated TFC may be laminated directly to the core of the substrate. In another embodiment, the roughening of one of the bonding surfaces illustrated in IC package 10 of FIGS. 1-4 may be combined with the patterning after lamination illustrated by the IC package 80 of FIGS. 5-7.

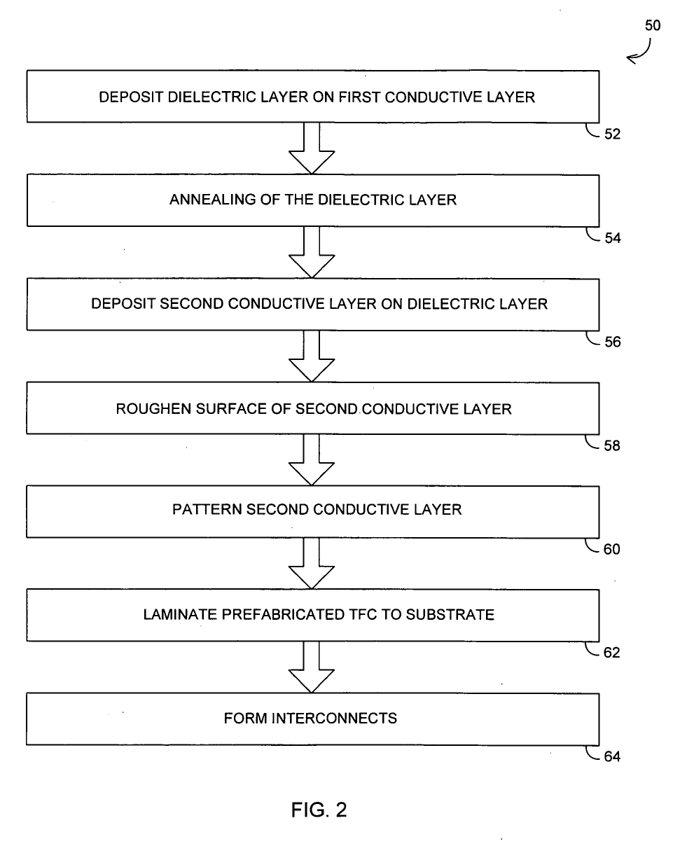

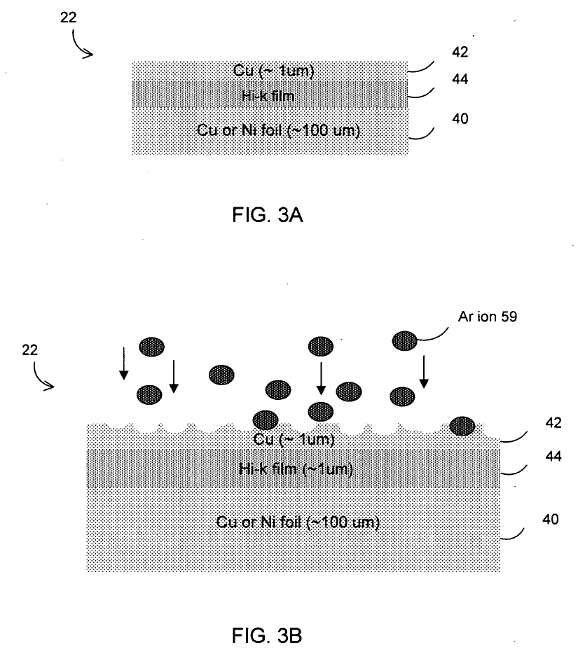

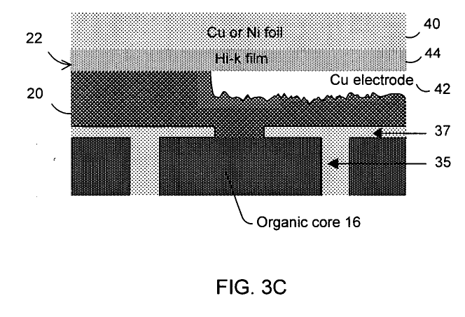

FIG. 2 shows a process flow 50 for fabricating the IC package 10 of FIG. 1. Additionally, FIGS. 3A-3C show cross-sectional views of the IC package 10 of FIG. 1 as it is built up during the process flow 50 of FIG. 2. Referring to FIGS. 1-3, the process flow 50 of FIG. 2 provides for lamination of TFC to the substrate 12 with a surface roughening stage for the conductive layers 40 and 42 of FIG. 1. The process flow 50 may use one of various non-wet roughening techniques (e.g. sputter bias etching after electrode layer sputtering, powder blasting or laser surface structuring processes) to increase the surface roughness of the conductive layers 40 and 42 and thereby improve the adhesion between the build-up layers 18 and 20 and conductive layers 40 and 42, respectively. As a result of the process flow 50, the thin film capacitor 22 may be laminated onto the substrate 12 with reduced concerns about de-lamination during substrate building process. The process flow 50 will now be described in detail.

Referring to FIGS. 1-2, at a stage 52 of the process flow 50, the hi-k ceramic thin film dielectric layer 44 (BST or other type of capacitive ceramic film) may be deposited on the conductive layer 40, which may be a metal foil (Cu or Ni) and may have a thickness of approximately in the range of 100 um thick. Chemical solution deposition (CSD), sputtering, chemical vapor deposition (CVD), multi-layer ceramic capacitor (MLCC) green sheet technology or other techniques may be used to deposit the dielectric layer 44 on the conductive layer 40. Next, at a stage 54, the dielectric layer 44 is annealed (for BST annealed at 700-1000 C.) in a reducing atmosphere. Thereafter, at a stage 56, the conductive layer 42 (which may be Cu) may be deposited onto the dielectric layer 44 using a physical vapor deposition (PVD) method (e.g., sputtering). FIG. 3A shows the dielectric layer 44 being sandwiched between the conductive layers 40 and 42 after the stage 56 in the formation of a prefabricated TFC 22.

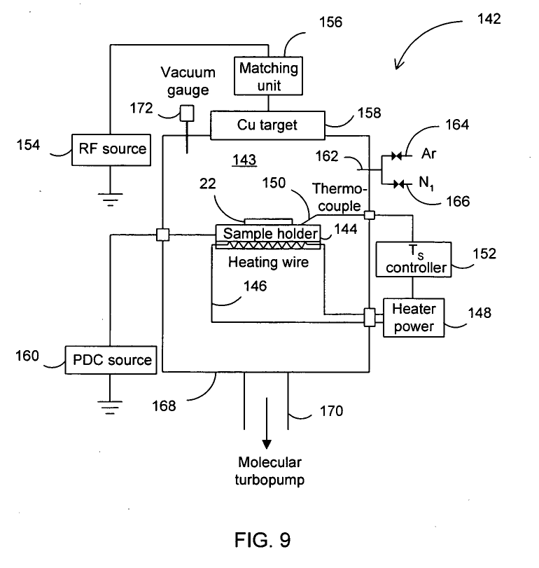

At a stage 58, the surface of the conductive layer 42 may be roughened through dry treatment by sputter etch, power blasting or laser structuring methods, as previously mentioned. In another embodiment, both the conductive layers 40 and 42 may be roughened. FIG. 3B illustrates the sputter etch process for the conductive layer 42, which is undertaken by use of ion bombardment by Argon ions 59. The hi-k ceramic dielectric layer 44 (˜1 um) may be very fragile to most acids. Even weak acids may preferentially attack the grain boundary of hi-k films and degrade their electrical performance. Thus, wet coating methods (e.g., electro-less or electroplating) may not be suitable to increase the thickness of the electrode layers of thin film capacitors since the dielectric layer 44 could be damaged in the wet baths. It should be noted that the sputter etch may be undertaken in the same sputtering chamber right after the sputter deposition of thin film conductive layer 42, as will be discussed further in a description of a sputtering apparatus of FIG. 9. In summary, at least the surface of the conductive layer 42 may be micro-mechanically treated to increase the roughness using bias sputter etch or other roughing methods not involving wet coating. In other embodiments to be described hereinafter, the surface of the substrate 12 may be roughened instead of the conductive layer 42 or both the conductive layer 42 and the substrate 12 may be roughened.

After the roughening of at least the conductive layer 42, at a stage 60, the conductive layer 42 may be patterned for the various interconnects. The conductive layer 40 also may be patterned at this stage. Upon completion of the stage 60, the prefabrication of the TFC 22 is complete and includes the above-described stages 52, 54, 56, 58 and 60. In addition to the formation of the prefabricated TFC 22, that portion of the substrate 12 to which the prefabricated TFC 22 will be laminated also may be fabricated. In one embodiment, this partial formation of the substrate 12 may include forming the core 16 and the PTH vias 35 through the core 16, depositing the via pads 37 and 38 on the core 16, depositing the build-up layers 20 and 21, forming the vias 36 in the build-up layers 21 and forming the land pads 32 on the build-up layer 20.

At a stage 62, the prefabricated TFC 22 may be laminated to the partially formed substrate 12 through an interface between roughened, patterned conductive layer 42 and an exposed surface of the build-up layer 20. This stage 62 may also include thinning the conductive layer 42 after lamination. The lamination stage may use any suitable lamination process. One such lamination process may include placing the substrate 12 with the TFC 22 positioned thereon into a rubber press to remove voids in a vacuum. Next, the substrate 12/TFC 22 combination may be placed in a stainless press at an increased preset pressure and temperature to flatten the build-up layer 20. Thereafter, the substrate 12/TFC 22 combination may be hardened through thermal treatment. As shown in FIG. 3C, the TFC 22 may be laminated to the build-up layer 20 as achieved during the stage 62. In FIG. 3C the conductive layer 42 is shown partly etched (roughened) as achieved during the stage 58 and partly patterned as achieved during the stage 60. The via pads 37 and PTH vias 35 are also shown in FIG. 3C.

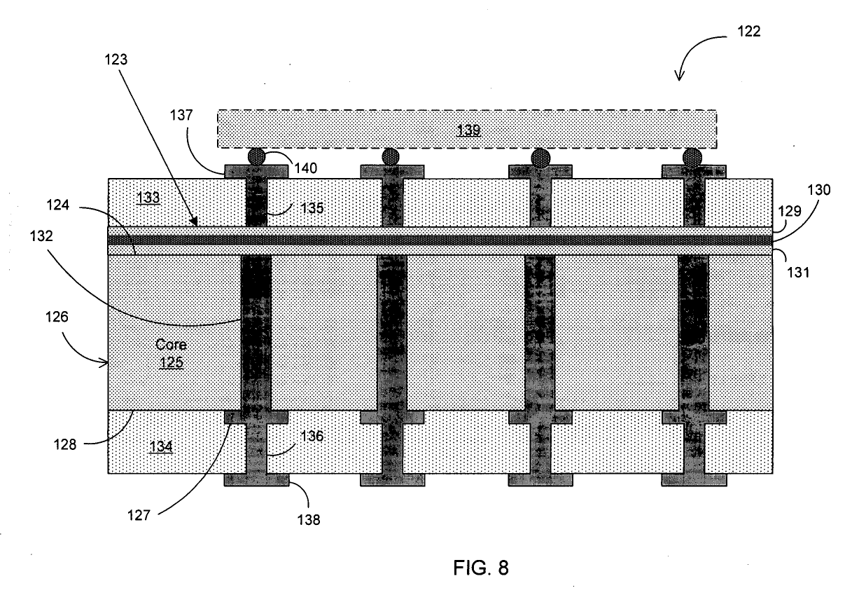

In another embodiment to be described hereinafter with respect to FIG. 8, the TFC may be laminated directly to an exposed surface of a core of a substrate. The exposed surface of the substrate 12, be it the exposed surface of the build-up layer 20 or the exposed surface of the core, to which the TFC 22 is laminated may be referred to as the “bonding surface” of the substrate 12.

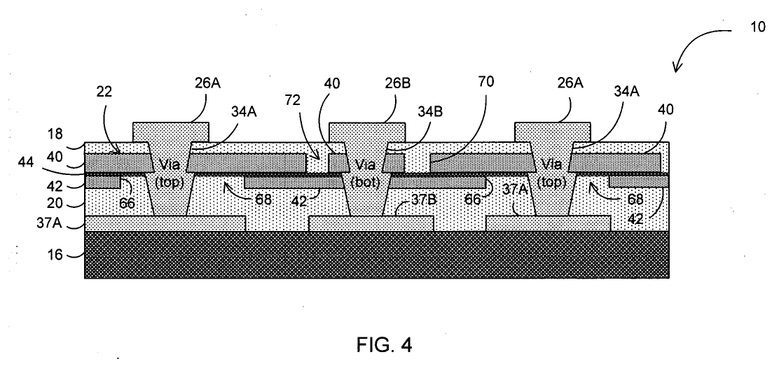

At a stage 64, the build-up layer 18 may be deposited on the TFC 22 and via drilling and filing for forming interconnects (e.g., vias 34) may be undertaken using laser or mechanical drilling. In FIG. 4 (to be discussed hereinafter), the completed interconnect structure of the TFC vias 34 is shown in detail. In summary, the process flow 50 may provide a reliable lamination process between prefabricated TFC 22 and substrate 12 without de-lamination issues.

Before the sputter etch process of the conductive layer 42, a sputtering process may be performed using a sputtering apparatus to deposit the conductive layer 42. Next, the sputter etch process for roughening the conductive layer 22 may be performed in the same chamber right after the sputter deposition of the conductive layer 42. One illustrative sputtering apparatus is shown in FIG. 9 (to be discussed hereinafter). In summary, the adhesion of sputtered conductive layer 42 to the substrate 12 may be made to provide a better bond due to the finely roughened TFC surface by ion bombardment during sputter etch or a like roughening process to be discussed hereinafter.

As previously mentioned, in other embodiments, the surface of the substrate 12 may be roughened instead of the surface of the conductive layer 42 or both the surfaces of the substrate 12 and the conductive layer 42 may be roughened to improve bonding adhesion. The above-described ion etch may not be fully effective for a polymer film, such as the build-up layer 20. However, the ion etch applied to the build-up layer 20 may improve the adhesion in that the ions may remove adsorbed water on the surface or inside of the build-up layer 22. In general, other roughening methods (e.g., polymer wet etching) described hereinafter are more desirable for roughening the surface of the substrate 12.

In another method for surface roughening, a power blasting method may give a mechanical impact to the substrate 12 to make a rough surface.

In yet another method of surface roughening, the use of a laser is a viable non-contact method that may be used to structure the surface of either the organic build-up layer 20 of the substrate 12 and/or the bottom electrode conductive layer 42 of the TFC 22 for improved adhesion upon lamination. The laser also may be used to roughen the surface of the top conductive layer 40. The structuring of the surface(s) with a laser means that laser energy is being used to introduce a surface roughness that is later used as a mechanical or chemical bonding mechanism between the two surfaces. The laser-introduced surface roughening in case of organic build-up layer 20 of the substrate 12 may be generated by laser ablation of a desired pattern across the dielectric surface of the build-up layer 20. However, in case of the roughening of the conductive layers 40 and 42, two approaches may be available: (1) laser ablation of a desired pattern on the conductive layers 40 and/or 42 (similar to roughening the build-up layer of the substrate 12) or (2) laser induced surface melting of the conductive layers 40 and 42. In case of the latter option, the laser melts a thin surface layer of the metal of the conductive layer 40 and/or conductive layer 42, and these layers 40 and/or 42 will solidify into a rougher surface due to the rapid thermal quenching inherently involved in the laser-metal interaction. The laser processing parameters and the laser source both may be adjusted to insure a certain surface roughness level. In another embodiment wherein the TFC is directly laminated to the core of the substrate (to be discussed hereinafter with respect to FIG. 8), these power blasting and laser methods of surface roughening also may be used for roughening the surface of the core and a metal clad core as well.

Referring to FIG. 4, an enlarged segment of the completed substrate 12 of FIG. 1 is shown. In one embodiment, the layers of the substrate 12 may have the following thicknesses: the build-up layer 18 (approximately 25 um thickness), the TFC 22 with the conductive layer 40 (approximately 15 um thickness), the dielectric layer 44 (approximately 1 um thickness), and the conductive layer 42 (approximately 5 um of thickness); the build-up layer 20 (approximately 25 um of thickness); and conductive metal via pads 37 (approximately 25 um of thickness). Also illustrated are the core 16, the die pads 26 (including die pads 26A and 26B), the vias 34 (including vias 34A and 34B), and metal via pads 37 (including via pads 37A and 37B), which were previously discussed with respect to FIG. 1. As more specifically shown in FIG. 4, the vias 34 may include the vias 34A which electrically couple the die pads 26A, the top conductive layer 40, and metal via pads 37A and include the vias 34B which electrically couple the die pads 26B, the bottom conductive layer 42, and the metal via pads 37B. In one embodiment, the vias 34A and vias 34B may alternate. The die pads 26A, vias 34A, top conductive layer 40, and via pads 37A may be coupled to the power supply Vcc and the die pads 26B, vias 34B, bottom conductive layer 42, via pads 37B may be coupled to the ground Vss. In another embodiment, the power and ground voltage may be switched for these components.

Referring to FIG. 4, the conductive layer 42 may be patterned (metal removed) during the stage 60 of FIG. 2 to form a plurality of holes 66 configured and arranged to provide spaces (gaps) 68 surrounding the vias 34A. The spaces 68 may be filled with a dielectric material so as to insulate the vias 34A from the conductive layer 42. Likewise, the conductive layer 40 may be patterned (metal removed) to form a plurality of holes 70 configured and arranged to provide spaces (gaps) 72 surrounding the vias 34B. The spaces 72 may be filled with a dielectric material so as to insulate the vias 34B from the conductive layer 40. In one embodiment, the metal via pads 37 may have a width of about 200 um and be spaced-apart from each other by 75 um.

It should be noted that since the top conductive layer 40 extends over the spaces 68 around the vias 34A and overlaps the conductive layer 42, the holes 66 need to be patterned prior to lamination of the TFC 22 to the build-up layer 20. Hence, in the process flow of FIG. 2, the patterning stage 60 of the conductive layer 42 occurs prior the lamination stage 62 in this embodiment.

As previously described, embedding hi-k dielectric thin films into an organic substrate directly may not be feasible due to the low melting point of the substrate 12. This may necessitate preparation of the prefabricated TFC 22, which may then be laminated onto the build-up layer 20 of the substrate 12. However, the lamination of the prefabricated TFC 22 to substrate 12 may create its own difficulty, and that has to do with the previously-mentioned lamination alignment accuracy. To better understand this lamination alignment issue, reference is made to FIGS. 2 and 4. During the lamination stage 62 of FIG. 2, the patterned holes 66 in the conductive layer 42 need to be aligned with its corresponding metal via pads 37A in the build-up layer 20. This alignment may be a difficult task and frequently leads to inaccurate, non-aligned results where the position of laminated TFC 22 relative to the via pads 37 may be shifted significantly after the lamination stage 62. In another embodiment of the present invention to be described hereinafter with respect to FIG. 5, the TFC may be patterned after the lamination process, thereby reducing this lamination alignment problem.

Referring to FIG. 5, an IC package 80, in accordance with another embodiment, is shown. In FIG. 5 a segment of a substrate 82 of the IC package 80 is shown that corresponds in size to the segment shown in FIG. 4. The overview description of the IC package 10 in FIG. 1 is equally applicable to the IC package 80 and will not be repeated. Those components not modified between FIGS. 1 and 5 will retain the same reference numbers.

The IC package 80 includes the substrate 82 having a TFC 83 sandwiched between a pair of build-up layers 84 and 86 made of a dielectric material 87, with build-up layer 86 being formed on the core 16 (not changed). The materials used may be the same as the first embodiment of FIGS. 1-4. More specifically, the build-up layers 84 and 86 may be comprised of an organic material such as ABF. In one embodiment, the IC package 80 may include a first surface 88 having an array of die pads 90 (which include die pads 90A and 90B) for electrically coupling the substrate 82 to a die. The TFC 83 is a multilayer structure with at least one pair of conductive layers 92 and 94 coupled between a power supply (supply voltage Vcc) and a ground (ground voltage Vss). The conductive layers 92 and 94 may be thin film electrode layers formed from, for example, copper (Cu) or nickel (Ni) foils. The conductive layers 92 and 94 are separated by a dielectric layer 96. The dielectric layer 96 may a thin film formed of a hi-k ceramic material with a dielectric constant (600-4000). In one embodiment, the hi-k ceramic material may be BaSrTiO₃ (BST).

In one embodiment, the IC package 80 may further include a plurality of vias 102 (including vias 102A and 102B), vias 104, and metal via pads 106 (including via pads 106A and 106B) which form part of the electrical paths for power and ground. The vias 102A extend between the die pads 90A and the via pads 106A. The vias 104 extend between the die pads 90A and the top conductive layer 92. Vias 108 extend between the die pads 90B and the via pads 106B and are electrically connected to bottom conductive layer 94 at a position between the die pads 90B and the via pads 106B. Each combination of the via 102A, the die pad 90A, and the via 104 defines a bridge connector 110 for coupling the via pad 106A to the top conductive layer 92. In other words, each bridge connector 110 may include one of the die pads 90 and two downward extending integral portions: one of the vias 102A and one of the vias 104, which combine to define a hook-like configuration for the bridge connector 110. In one embodiment, the vias 90A and 90B may alternate; hence, a bridge connector 110 may occur with every other die pad 90. In one embodiment, the bridge connector 110 may be part of the path for providing the supply voltage Vcc. The die pads 90A may be used for power voltage Vcc and the die pads 90B may be used for ground voltage Vss. In another embodiment, the voltages may be switched. The remainder to the IC package 80 may be the same as illustrated in FIG. 1.

In one embodiment, the layers of the substrate 82 may have the following thicknesses: the build-up layer 84 (approximately 25 um thickness), the TFC 83 with the conductive layer 92 (approximately 15 um thickness), the dielectric layer 96 (approximately 1 um thickness), and the conductive layer 94 (approximately 5 um of thickness); the build-up layer 86 (approximately 25 um of thickness); and the conductive metal via pads 106 (approximately 25 um of thickness). The via pads 106 may have a width of 190 um and may be spaced apart from each other by 75 um.

As with the fabrication of the IC package 10 of FIG. 4, the low melting point of substrate 82 makes it desirable to undertake the lamination of a prefabricated TFC 83 onto the substrate 82 having organic materials. But unlike the IC package 10 of FIG. 4, the TFC 83 may be patterned after lamination; hence, the alignment difficulty may be significantly reduced. In other words, after the lamination of TFC 83, the layers of the TFC 83 may be patterned for electrical connections as opposed to laminating a pre-patterned TFC as undertaken with the IC package 10 of FIGS. 1-4. Hence, a separately fabricated TFC 83 without any patterned structures may be laminated to achieve a reliable structure for integrated TFC 83 without requiring high lamination alignment accuracy. Thus, this also may provide a low cost lamination process.

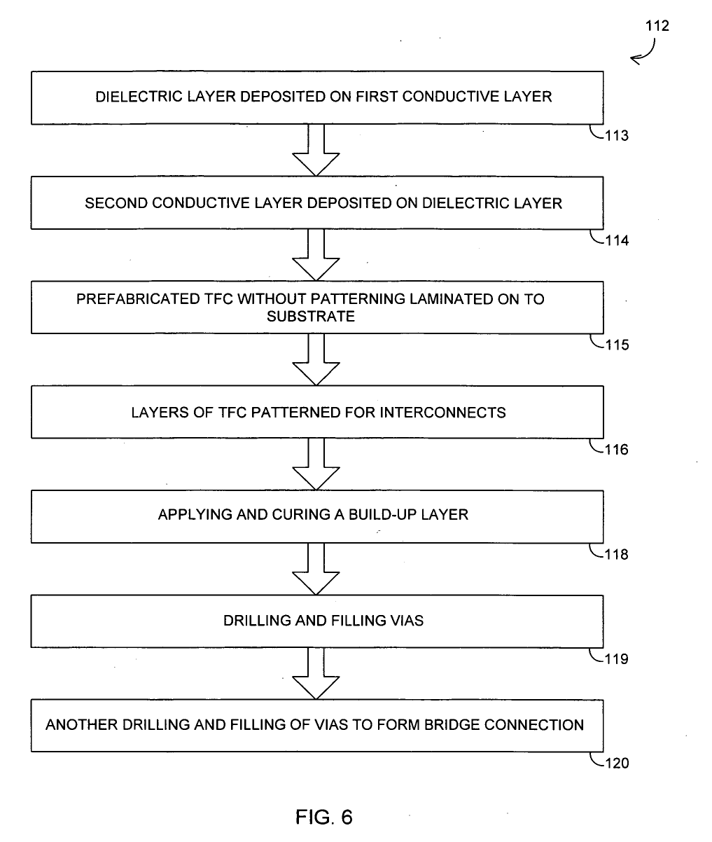

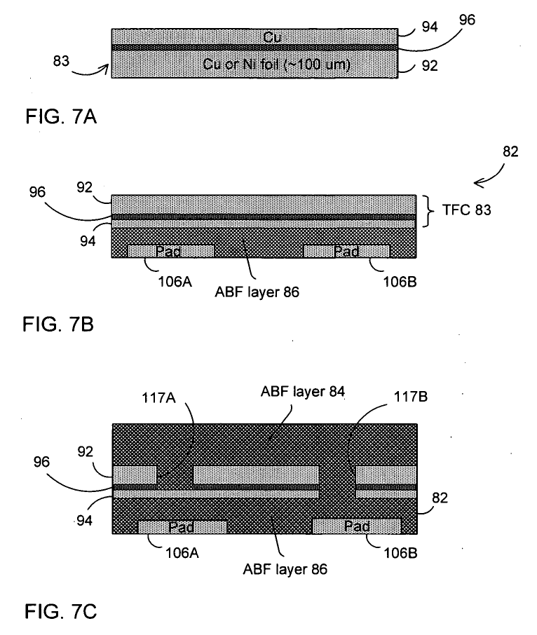

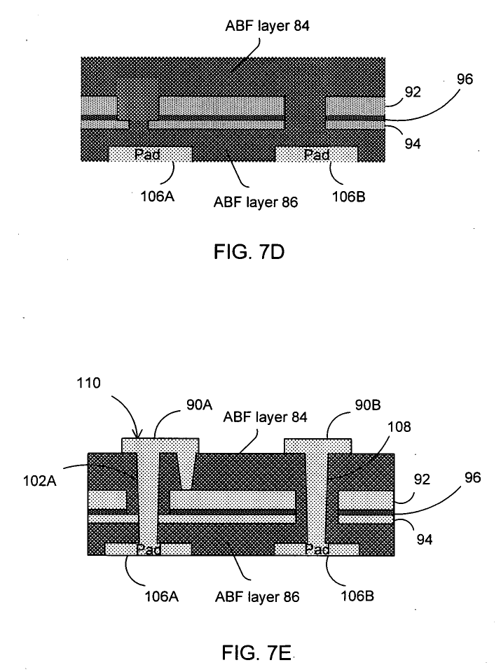

FIG. 6 illustrates a process flow 112 for fabricating the IC package 80 of FIG. 5. Additionally, FIGS. 7A-7E show cross-sectional views of the IC package 80 as it is built up during the process flow 112 of FIG. 5. Referring to FIGS. 5-6, the process flow 112 provides for lamination of TFC 83 to a substrate 82 with patterning occurring after lamination.

At a stage 113 of FIG. 6, the dielectric layer 96 (which may be a thin hi-k film) may deposited on the conductive layer 92, which may be a metal foil (Cu or Ni). For example, the dielectric layer 96 may be BST or other type of capacitive ceramic film. The thickness may be approximately 1 um. Chemical solution deposition (CSD), sputtering, chemical vapor deposition (CVD), multi-layer ceramic capacitor (MLCC) green sheet technology or other techniques may be used to deposit the dielectric layer 96. The conductive layer 92 may have a thickness in the range of approximately 100 um.

Next, at a stage 114 of FIG. 6, the dielectric layer 96 may be annealed (for BST annealed at 700-1000 C.) in a reducing atmosphere. Then the conductive layer 94 may be deposited onto the dielectric layer 96 to form a prefabricated (preformed or separately fabricated) TFC 83 without any patterned structure. The conductive layer 94 may be deposited using sputtering and may in the range of approximately 5 um. The prefabricated TFC 83 is shown in FIG. 7A.

At this point the prefabrication of the TFC 83 is complete with the implementation of the above-described stages 113 and 114. Also, prior to the next stage of laminating the TFC 83 to the substrate 82 (as will be described hereinafter), the substrate 82 is partially completed. More specifically, with reference to FIGS. 1 and 5, the formation of the partial substrate 82 may include the following stages: forming the core 16, forming PTH vias 35 through the core 16, forming the via pads 38 and via pads 106 on opposed sides of the core 16, depositing the organic build-up layers 21 and 86 on opposed sides of the core 16 over the via pads; forming the vias 36 in the build-up layer 21, and forming the land pads 32. In another embodiment, the build-up layer 86 may not be included so that the TFC may be directly laminated to the core, as is illustrated in FIG. 8 to be described hereinafter.

At stage 115 of FIG. 6, the prefabricated TFC 83 without any patterned structure may be laminated to the organic build-up layer 86 of the substrate 82 in one embodiment as shown in FIG. 5 or laminated to the core of the substrate in another embodiment as is illustrated in FIG. 8 to be described hereinafter. More specifically, after the TFC 83 is mounted to the build-up layer 86 as shown in FIG. 5, then curing process may be performed. Thus, high alignment accuracy may not be required during lamination process. In FIG. 7B, the TFC 83 is shown laminated to the build-up layer 86. The remainder of the substrate 82 is the same as shown in FIG. 1 (e.g., the core 16, PTH vias 35, vias 36, via pads 38 and build-up layer 21). After lamination, this stage 115 may also include thinning the build-up layer 84 using chemical-mechanical polishing (CMP) or wet etching. Note that in FIG. 7A the conductive layer 92 is initially at approximately 100 um, but that in FIG. 5 the conductive layer 92 is approximately 15 um.

After the lamination, at a stage 116 of FIG. 6 the layers of the TFC 83 may be patterned for electrical connections using wet etching, dry etching or laser via drilling as illustrated by the via holes 117A and 117B formed in the TFC 83 in FIG. 7C. At a stage 118, the upper build-up layer 84 may be applied and cured so as to result in the structure shown in FIG. 7C. After applying and curing the build-up layer 84, at stage 119 of FIG. 6 additional via drilling may be performed as shown in FIG. 7D to configure the conductive layer 94 to receive the via 102A.

At a stage 120 of FIG. 6, another via drilling and filling may be performed to connect power signal to the top conductive layer 92 of the TFC 83 by use of a bridge connection forming the bridge connector 110. Additionally, the die pads 90B and the other necessary interconnects may be formed, as shown in FIG. 7E. The bridge connectors 110 allow for patterning after lamination. Without bridge type connectors 110, bottom conductive layer 94 of TFC 83 should be patterned before the lamination for electrical connections and thereby necessitating high lamination alignment accuracy.

In summary, the TFC 83 may be fabricated separately from the substrate 82 due to the high temperature process of hi-k films (dielectric layer 96) at furnace temperatures (e.g., 600-1000 C.). The process flow 112 does not require patterning of the layers of the TFC 83 before the lamination stage, which is in contrast to the process flow 50 of FIG. 2. Instead, after the lamination stage the TFC 83 may be patterned for electrical connections. Thus, an un-patterned TFC 83 may be laminated to the build-up layer 86 (or the core) without the need of high risk lamination alignment accuracy. As a consequence, the lamination process of TFC 83 may be more reliable and may be a low cost process to increase capacitance area. The integrated TFC 83 may provide low inductance and a reduced number of PTH vias in addition to the capacitance. In one embodiment, the reliable lamination process without the requirement of high alignment accuracy by use of bridge connectors 110 of TFC 83.

Referring to FIG. 8, an IC package 122, in accordance with another embodiment of the present invention, is illustrated. In this embodiment, a TFC 123 may be directly laminated to a bonding surface 124 of a core 125 of a substrate 126. This direct bonding of the TFC 123 to the core 125 may be accomplished because of the absence of via pads on the bonding surface 124. A plurality of via pads 127 may be included on an opposed side 128 of the core 125. The TFC 123 may include a top conductive layer (electrode) 129, a dielectric layer 130, and a bottom conductive layer (electrode) 131. The core 125 may include a plurality of PTH vias 132, with part of them coupling via pads 127 to the top conductive layer 129 and part of them coupling via pads 127 to the bottom conductive layer 131. The substrate may include build-up layers 133 and 134. The build-up layers 133 and 134 include vias 135 and 136, respectively. Mounted on the surfaces of the build-up layers 133 and 134 are die pads 137 and land pads 138, respectively. A die 139 may be coupled to the die pads 137 via solder bumps 140. Since the differences between the IC package 10 of FIG. 1 and the IC package 122 of FIG. 8 reside in the structures of the partial substrate to which the TFC is laminated, the process flow of FIG. 2 may be used to fabricate the IC package 122. In summary, the TFC 123 may be laminated directly to the core 125 instead of a build-up layer on the core as is undertaken with the IC package 10 of FIG. 1.

In another embodiment according to the present invention, the IC package 122 of FIG. 8 may be modified to include the bridge connectors similar to the bridge connectors of FIG. 5, except that each of these bridge connectors may have a die pad with one of the vias extending from the die pad all the way through the core 125 to connect with one of the via pads 127. The other via connected to the die pad extends from the die pad to the top conductive layer 129 in the same manner as illustrated in FIG. 5. In other words, the one of the vias of each of the bridge connectors extends to a via pad 127 of FIG. 8 for this embodiment, since there are no via pads on the opposite side of the core 125, which has become the bonding surface 124. In both embodiments allowing for patterning after lamination (this embodiment and the embodiment of FIG. 5), the longer via extending from the die pad of a bridge connector electrically connects to the first available via pad, which are located on opposed sides of the core (via pad 127 in FIG. 8 and via pad 106A in FIG. 5). The process flow illustrated in FIG. 6 may be used to fabricate this IC package.

Referring to FIG. 9, there is shown a sputtering apparatus 142, which is an example of one of many possible sputtering apparatus that may be used with the sputtering stages of the process flow of FIGS. 2 and 6 and in particular, may be used for sputtering etch function of the process follow of FIG. 2 which is used for roughening. The use of the sputtering apparatus 142 for fabricating the IC package 10 of FIG. 2 will now be discussed. The apparatus 142 may include a sputter chamber 143 having a sample holder 144. The sample holder 144 may hold the sample TFC during the surface roughening stage of the process flow of FIG. 2. The sample holder 144 may have a heating wire 146 coupled to a heater power source 148. A thermo-couple 150 may measure the temperature of the sample holder 144, with the temperature signal Ts being fed to a temperature controller 152, which may regulate the temperature of the sample holder 144 by controlling the heater power source 148. A radio frequency (RF) bias voltage source 154 may be coupled to a matching unit 156 (RF noise reduction), which in turn may be coupled to a Cu target electrode 158. The Cu target electrode 158 may form one electrode and the sample holder 144 may form another electrode coupled to ground via a power delivery controller (PDC) source 160, with an electrical field being applied between the two electrodes. Argon gas for bombarding the surface of the conductive layer of the TFC may be introduced into the sputter chamber 143 through a gas inlet 162 from a gas source (not shown). Other gases, such as nitrogen, may also be introduced into the chamber 143 by way of values 164 and 166. A bottom wall 168 of the chamber 143 may have an exhaust pipe 170 coupled to an exhaust device (not shown), such as a molecular turbopump to provide the necessary degree of vacuum, i.e., the desired low pressure. A vacuum gauge 172 may measure the pressure within the sputter chamber 143. Although a particular sputtering apparatus 142 is described above, it should be appreciated that the sputtering apparatus 142 is provided for illustrative purposes only and that a variety of prior art plasma etching or reactive ion etching equipment may be used.

Referring to FIGS. 3B and 9, the RF bias voltage may be applied to the TFC 22 after the TFC 22 is loaded at the sample holder 144. A process or reactive gas, in the form of argon, may be introduced into the chamber 143 through the inlet 162 into a space between the electrodes 158 and 144. In this region, the RF excitation may ionize the argon gas in a reduced pressure environment to convert the argon gas into a plasma having free radicals to provide the bias sputtering etch. More specifically, Argon ions bombard the TFC 22 with high kinetic energy and roughen the surface of the TFC 22 mechanically as shown in FIG. 3B. During this process, the chamber 143 may be exhausted through the exhaust pipe 170 to maintain a predetermined low pressure level.

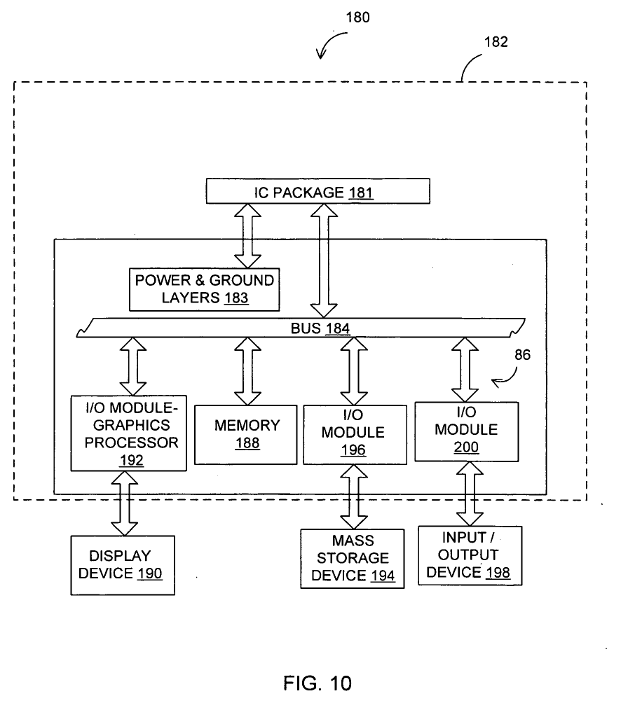

Referring to FIG. 10, there is illustrated a system 180, which is one of many possible systems in which an IC package 181 may be used. The IC package 181 may comprise the IC packages 10, 80, 122 of FIGS. 5, 6 and 8, respectively, or other IC package described above. In this illustrative system 180, a die embedded in the IC package 181 may be a processor. The IC package 181 may be directly coupled to a PCB 182 or indirectly coupled by way of a socket (not shown). The PCB 182 may be a motherboard. In this embodiment, the power/ground land pads of the IC package 181 may be coupled to the power and ground planes 183 in the PCB 182. The I/O signal land pads of the IC package 181 may be coupled to a bus 184. The bus 184 interconnects the IC package 181 (and therefore the processor) with one of more devices 186. The I/O signals on the bus 184 may include data, address, and control signals.

In this illustrative embodiment of the system 180, the devices 186 may include a main memory 188 and a plurality of input/output (I/O) modules for external devices or external buses, all coupled to each other by the bus 184. More specifically, the system 180 may include a display device 190 coupled to the bus 184 by way of an I/O module 192, with the I/O module 192 having a graphical processor and a memory. The system 180 may further include a mass storage device 194 coupled to the bus 184 via an I/O module 196. Another I/O device 198 may be coupled to the bus 184 via the I/O module 200. Additional I/O modules may be included for other external or peripheral devices or external buses. Examples of the memory 188 include, but are not limited to, static random access memory (SRAM) and dynamic random access memory (DRAM). The memory 188 may include an additional cache memory. Examples of the mass storage device 194 include, but are not limited to, a hard disk drive, a compact disk drive (CD), a digital versatile disk driver (DVD), a floppy diskette, a tape system and so forth. Examples of the input/output devices 198 may include, but are not limited to, devices suitable for communication with a computer user (e.g., a keyboard, cursor control devices, microphone, a voice recognition device, a display, a printer, speakers, and a scanner) and devices suitable for communications with remote devices over communication networks (e.g., Ethernet interface device, analog and digital modems, ISDN terminal adapters, and frame relay devices). In some cases, these communications devices may also be mounted on the PCB 182. The bus 184 may include a single bus or as a combination of buses (e.g., system bus with expansion buses). Examples of the bus system 184 include, but are not limited to, a Peripheral Component Interconnect-X (PCI-X) bus, peripheral control interface (PCI) bus, and Industry Standard Architecture (ISA) bus, and so forth. Depending upon the external device, I/O modules internal interfaces may use programmed I/O, interrupt-driven I/O, or direct memory access (DMA) techniques for communications over the bus 184. Depending upon the external device, external interfaces of the I/O modules may provide to the external device(s) a point-to point parallel interface (e.g., Small Computer System Interface—SCSI) or point-to-point serial interface (e.g., EIA-232) or a multipoint serial interface (e.g., Fire Wire).

Although specific embodiments have been illustrated and described herein, it will be appreciated by those of ordinary skill in the art that any arrangement which is calculated to achieve the same purpose may be substituted for the specific embodiment shown. This application is intended to cover any adaptations or variations of the present invention. Therefore, it is manifestly intended that this invention be limited only by the claims and the equivalents thereof.

What is claimed is:

1. A method of fabricating an integrated circuit package, comprising:
prefabricating a film capacitor including
forming a first conductive layer,
depositing a dielectric layer on the first conductive layer, and
depositing a second conductive layer on the dielectric layer;
forming a substrate; and
laminating the prefabricated film capacitor to the substrate.

2. The method according to claim 1, further comprising:
roughening a selected one of the second conductive layer and a bonding surface of the substrate prior to the laminating of the prefabricated film capacitor; and
wherein the laminating of the prefabricated film capacitor includes laminating the second conductive layer to the bonding surface.

3. The method according to claim 1, wherein the roughening of the selected one of the second conductive layer and a bonding surface of the substrate including roughening using laser irradiation.

4. The method according to claim 1, wherein the depositing of the second conductive layer on the dielectric layer includes sputtering the second conductive layer onto the dielectric layer in a sputtering apparatus; and the method further comprises:
after the sputtering of the second conductive layer, roughening the second conductive layer with a sputtering etch in the sputtering apparatus prior to the laminating of the prefabricated film capacitor; and
wherein the laminating of the prefabricated film capacitor includes laminating the roughened second conductive-layer to the substrate.

5. The method according to claim 1, further comprising:
roughening a bonding surface of a core of the substrate; and
wherein the laminating of the prefabricated film capacitor includes laminating the prefabricated film capacitor to the roughened bonding surface.

6. The method according to claim 1, further comprising:
roughening a bonding surface of a build-up layer of the substrate; and
wherein the laminating of the prefabricated film capacitor includes laminating the prefabricated film capacitor to the roughened bonding surface.

7. The method according to claim 2, wherein the prefabricating of the film capacitor further includes patterning the prefabricated film capacitor prior to the laminating of the prefabricated film capacitor.

8. The method according to claim 1, further comprising:
patterning the prefabricated film capacitor after the laminating of the prefabricated film capacitor.

9. The method according to claim 8, wherein:
the laminating of the prefabricated film capacitor includes laminating the second conductive layer to the substrate; and
the forming of the substrate includes embedding a plurality of via pads in the substrate; and forming and configuring at least one bridge connector to electrically connect one of the plurality of via pads to the first conductive layer and to form a die pad.

10. The method according to claim 9, wherein the forming and configuring of the at least one bridge connector includes forming a first via disposed to electrically connect the die pad to the one pad via and a second via disposed to electrically connect the die pad to the first conductive layer.

11. The method according to claim 9, further comprising:
applying a first build-up layer over a core of the substrate;
applying a second build-up layer over the prefabricated film capacitor; and
wherein the embedding of the plurality of via pads includes mounting the plurality of via pads to the core; and the laminating of the second conductive layer includes laminating the second conductive layer to the first build-up layer.

12. The method according to claim 1, wherein the forming of the substrate includes forming a core and depositing an organic build-up layer on the core; and the laminating of the prefabricated film capacitor includes laminating the prefabricated film capacitor to the organic build-up layer.

13. The method according to claim 1, wherein the forming of the substrate includes forming an organic core; and the laminating of the prefabricated film capacitor includes laminating the prefabricated film capacitor to the organic core.

14. The method according to claim 1, further comprising:
after the laminating of the prefabricated film capacitor, depositing a build-up layer over the prefabricated film capacitor; and
mounting a plurality of die pads to the build-up layer.

15. The method according to claim 1, wherein the dielectric layer is formed from a hi-k ceramic material having a dielectric constant in a range of 600-4000.

16. The method according to claim 1, wherein the dielectric layer is formed of BaSrTiO₃.

17. The method according to claim 15, wherein a bonding surface of the substrate is formed of an organic material; and the laminating of the prefabricated film capacitor includes laminating the prefabricated film capacitor to the bonding surface.

18. An integrated circuit package, comprising:
a substrate including a plurality of first via pads embedded therein;
a die mounted to the substrate;
a prefabricated film capacitor embedded in the substrate and including a first conductive layer, a second conductive layer, and a dielectric layer disposed between the first and the second conductive layers; the second conductive layer being laminated to the substrate; and
the substrate further including at least one bridge connector configured and disposed to electrically connect one of the plurality of first via pads and the first conductive layer and to form a first die pad, with the first die pad being electrically coupled to the die.

19. The integrated circuit package according to claim 18, wherein the substrate further includes:
a core having the plurality of first via pads mounted thereon; and
a build-up layer disposed over the plurality of first via pads and having a bonding surface laminated to the second conductive layer.

20. The integrated circuit package according to claim 18, wherein the substrate further includes a core having a pair of opposed surfaces, with the second conductive layer being laminated to one of the surfaces and the plurality of first via pads being disposed on the other one of the surfaces.

21. The integrated circuit package according to claim 18, wherein the at least one bridge connector includes a first via disposed to electrically connect the first die pad to one of the plurality of first via pads and a second via disposed to electrically connect the first die pad to the first conductive layer.

22. The integrated circuit package according to claim 21, wherein the substrate further includes a plurality of second via pads embedded in the substrate; a plurality of second die pads disposed on the substrate; and a plurality of third vias disposed to electrically connect the plurality of second via pads, the second conductive layer, and the plurality of second die pads.

23. The integrated circuit package according to claim 22, wherein the at least one bridge connector has a hook-like configuration; the at least one bridge connector includes a plurality of bridge connectors forming a plurality of first die pads.

24. A system, comprising:
a printed circuit board having a bus;
an integrated circuit package including a die; the package including
a substrate including a core having a plurality of via pads mounted thereon, the substrate further including a bonding surface,
a prefabricated film capacitor embedded in the substrate and including a first conductive layer, a second conductive layer, and a dielectric layer disposed between the first and the second conductive layers; the second conductive layer being laminated to the bonding surface, and
the substrate further including at least one bridge connector configured and disposed to electrically connect one of the plurality of the via pads and the first conductive layer and to form a die pad, with the die pad being electrically coupled to the die; and
a mass storage device coupled to the bus.

25. The system according to claim 24, further comprising an input/output network interface module coupled to the bus and a main memory coupled to the bus.

26. The system according to claim 24, wherein the system is selected from a group consisting of a set-top box, an entertainment unit and a DVD player.

27. The system according to claim 24, wherein the at least one bridge connector includes a first via disposed to electrically connect the die pad to one of the plurality of via pads; and a second via disposed to electrically connect the die pad to the first conductive layer.

28. The system according to claim 24, wherein the substrate further includes a build-up layer disposed over the plurality of via pads, with the build-up layer having the bonding surface.

29. The system according to claim 24, wherein the core further includes a pair of opposed surfaces, with one of the opposed surfaces having the plurality of via pads and the other one of the opposed surfaces being the bonding surface.
